(19) United States
(12) Patent Application Publication
(10) Pub. No.: US 2010/0328121 A1
(43) Pub. Date: Dec. 30, 2010

(54) CIRCUIT TESTING

(75) Inventor: David Hamilton, Edinburgh (GB)

Correspondence Address: MOORE & VAN ALLEN PLLC, P.O. BOX 13706, Research Triangle Park, NC, 27709, US

(73) Assignee: Ateeda LTD, Edinburgh (GB)

(21) Appl. No.: 12/918,750

(22) PCT Filed: Mar. 11, 2009
(86) PCT No.: PCT/GB09/00659

§ 371 Date: Aug. 20, 2010

(30) Foreign Application Priority Data
Mar. 12, 2008 (GB) 0804555.1

(51) Int. Cl. H03M 1/10

(52) U.S. Cl. 341/120

(57) ABSTRACT

A method for testing a circuit that generates an n-bit pulse density modulated output in response to an input signal or combination of input signals, for example the analogue section (12) of an analogue to digital converter (25) that has an n-bit pulse density modulated output stream, the method comprising inputting a test signal to the circuit, converting the pulse density modulated output to an analogue signal and checking the actual analogue output against an expected output, thereby to identify any faults.

The present invention relates to a system and method for testing circuits that have a pulse density modulated output signal, and in particular the analogue part of an analogue to digital converter.

### BACKGROUND OF THE INVENTION

Analogue-to-digital converters (ADC) are electronic devices that convert continuous input signals, such as analogue voltage or current signals, to discrete digital numbers. The continuous input value changes with infinite voltage amplitude resolution between its limiting voltage ranges and at a rate determined by the frequency content of the signal. The digital output data is a sampled version of the input having limited voltage resolution described as the number of bits to represent each sample and the time resolution dictated by the sample rate described herein as the clock rate. Such devices are ubiquitous within electronic circuitry especially for example in CMOS mixed signal devices.

In normal operation, the input to the device consists of an analogue voltage and the final output consists of a digital data sequence representing the time varying input signal. In the case of a delta-sigma ADC, the device has both an analog processing section and a digital processing section. For sigma delta ADCs, the final digital output stream is obtained by taking the intermediate high frequency binary output from an analogue processing section of the ADC and using its digital processing stage to give a final digital output. To do this, the analogue section converts the amplitude of the input signal into a high frequency stream of binary pulses, which has a density representative of the precise input analogue voltage. A high input voltage produces a greater density of ones in the stream while a lower input voltage produces a greater density of zeros in the stream. A mid range input produces roughly equal numbers of ones and zeros in the stream. The average or other numerically processed number of ones and zero over a given period of time represents the precise input voltage.

A significant factor in the manufacture of ADCs is the test time and cost. This is affected by the cost of test equipment and the mode of test and time taken. Expensive and sophisticated analog test equipment is currently employed which can provided highly precise analog waveforms such as a ramp voltage extending over the input range allowing the final digital output to be checked against expected digital values for each input value on the ramp as it changes with time. This is a slow and therefore expensive test on expensive equipment.

### SUMMARY OF THE INVENTION

According to the present invention, there is provided a method of testing a circuit that has a pulse density modulated output, for example the analogue section of an analogue to digital converter that has a pulse density modulated output, the method comprising: inputting a test signal to the circuit; converting the pulse density modulated output to an analogue signal and checking the actual analogue output against an expected output.

Where the circuit under test is a sigma delta ADC, the pulse density modulated output from the analogue section is converted to an analogue signal before it enters the digital section.

The test circuit of the invention is very simple and allows complex circuits, such as ADCs, to be tested at any stage in manufacture, even before individual packaging of the devices.

Converting the pulse density modulated output to an analogue signal may involve filtering the pulse stream. Filtering the pulse stream may be done using an RC filter and/or an active analogue filter. The resistive part of the filter may be a switched capacitor resistor.

The method may involve inputting a digital test signal. The digital test signal may be binary or may have more than two levels. The digital input may be converted to accentuate its analogue characteristics prior to inputting it to the circuit under test.

The circuit under test may have an N-bit pulse density modulated signal output, where N is an integer of one or more. Where the digital output test signal from the analogue section has more than two levels the output may be described as a number density modulated output stream, rather than a pulse density modulated output stream

Checking the converted signal after re-conversion to an analogue signal may be done using a simple comparator. The comparator may be any one of a voltage comparator; a current comparator and a charge comparator.

The n-bit pulse density modulated output stream may comprise a single binary stream.

The n-bit pulse density modulated output stream may comprise a plurality of binary streams. In this case, the combination of streams represents or encodes, when processed over time, the analogue input voltage.

According to another aspect of the invention, there is provided a system for testing a circuit that has an n-bit pulse density modulated output stream in response to an input signal or combination of input signals, for example the analogue section of an analogue to digital converter that has an n-bit pulse density modulated output stream, the system comprising: means for inputting a test signal to the circuit; means for converting the pulse density modulated output to an analogue signal and means for checking the actual analogue output against an expected output.

The means for converting the pulse density modulated output to an analogue signal may comprise a filter, for example an RC filter and/or an active analogue filter.

The means for converting the pulse density modulated output to an analogue signal comprise an integrator.

The input signal may be a digital test signal, such as a binary signal or a signal that has more than two levels.

The n-bit pulse density modulated output stream may comprise a single binary stream. Alternatively, the n-bit pulse density modulated output stream may comprise a plurality of binary streams. The output pulses may be voltage, current or charge pulses.

Means may be provided for converting the digital input to an analogue signal prior to inputting it to the circuit under test. The converting means may comprise a filter, for example an RC filter and/or an active analogue filter. Alternatively, the means for converting the digital input to an analogue signal may comprise an integrator.

The means for checking the converted signal comprise a comparator. The comparator may be any one of a voltage comparator; a current comparator and a charge comparator.

The system may include means for using an optimised input test vector.

According to yet another aspect of the invention, there is provided a method for testing the digital part of a sigma delta ADC comprising causing the input of the digital part to be in a known starting state; inputting a known sequence comprising a binary pulse density modulated stream and comparing the digital output with an expected output.

According to still another aspect of the invention, there is provided a method for testing a sigma delta ADC comprising testing the analogue part and testing the digital part separately.

By separating out tests for the analogue and digital parts, there is provided an enhanced and improved method for ensuring the integrity of a sigma delta ADC. This can be done quickly and reliably using simple components and does not require significant amounts of processing power.

### BRIEF DESCRIPTION OF THE DRAWINGS

Various aspects of the invention will now be described by way of example only and with reference to the accompanying drawings, of which:

FIG. 1(a) is a view of a sigma delta ADC;

FIG. 1(b) is a block diagram of a sigma delta ADC in a test circuit;

FIG. 2 is series of graphs showing the inputs to and outputs from the test circuit of FIG. 1;

FIG. 3 is an expanded portion of the graphs of FIG. 2;

FIG. 4 shows output responses from a good circuit and a faulty circuits being a leaky integrating capacitor;

FIG. 5 shows output responses for a good circuit response against various faults, and

FIG. 6 is a block diagram of a digital device under test circuit, where the digital device is the digital part of a sigma-delta ADC.

### DETAILED DESCRIPTION OF THE DRAWINGS

The present invention provides a test for circuitry that converts an analogue input signal into a modulated density pulse stream. This test is generic and makes the simple assumption that the pulse stream density over time is a faithful representation of the input signal. Typically, an on-chip high order digital filter is used to extract the digital values from this pulse stream before the output is passed forward for use.

The invention is particularly suited for testing the analogue part of a sigma-delta ADC, separately from the digital part. To provide a complete test of a sigma-delta ADC, another aspect of the invention also provides a test for the digital part of the circuit. In terms of speed, reliability, sensitivity and complexity of equipment requirement and stage of manufacture when testing can be applied, significant gains can be made if the digital section of a delta sigma ADC is tested separately from the analogue section.

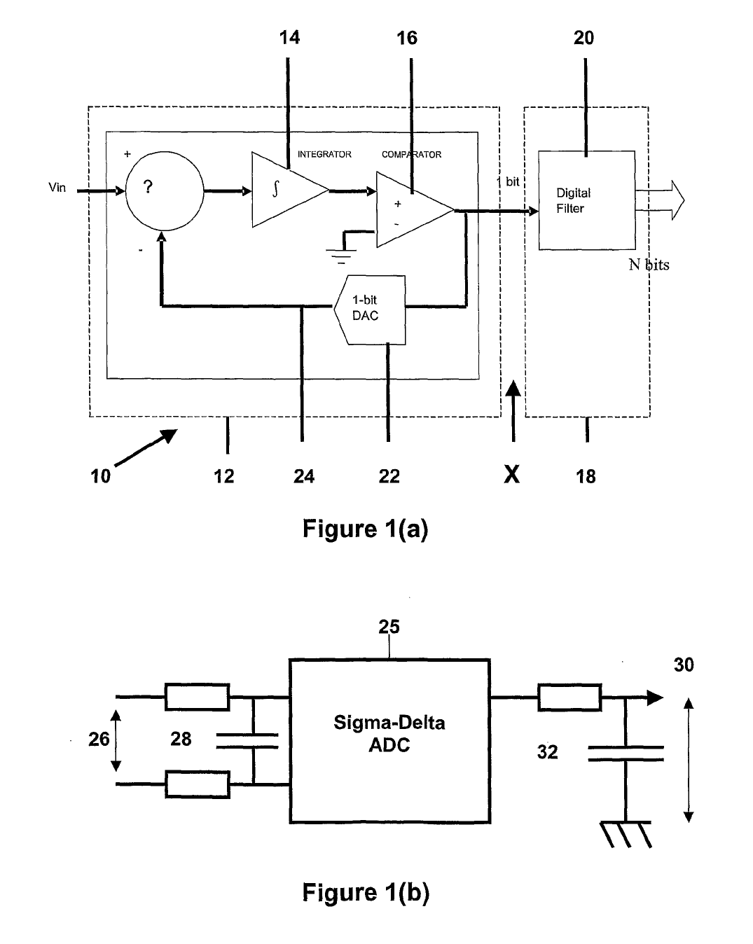

FIG. 1(a) shows the basic structure of a sigma-delta ADC 10. This has a first analogue part 12 that has an integrator 14 that is connected to an input of a comparator 16. Connected to the output of the comparator 16 is a second digital part 18 of the ADC that comprises a digital filter 20. Also connected to the comparator output is a one-bit DAC 22, which has an output 24 that is fed back to the analogue part input, and differenced from the ADC input before it passes in to the integrator 14.

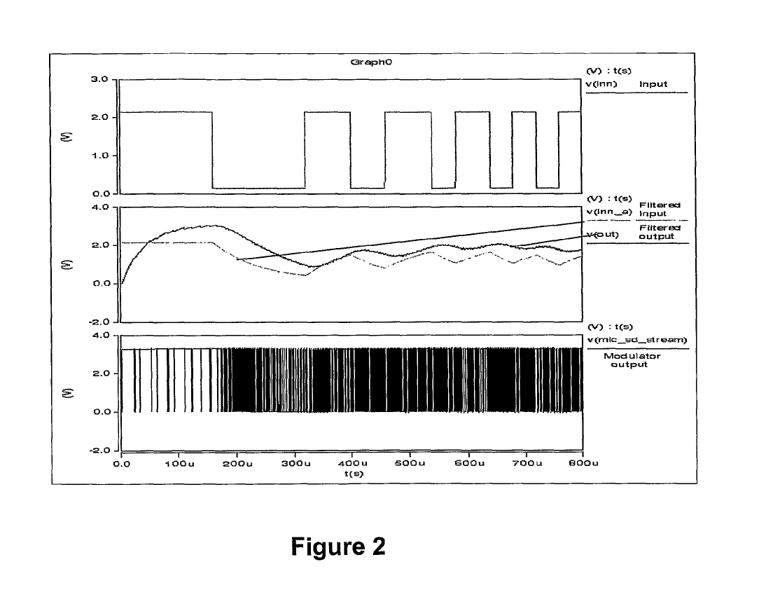

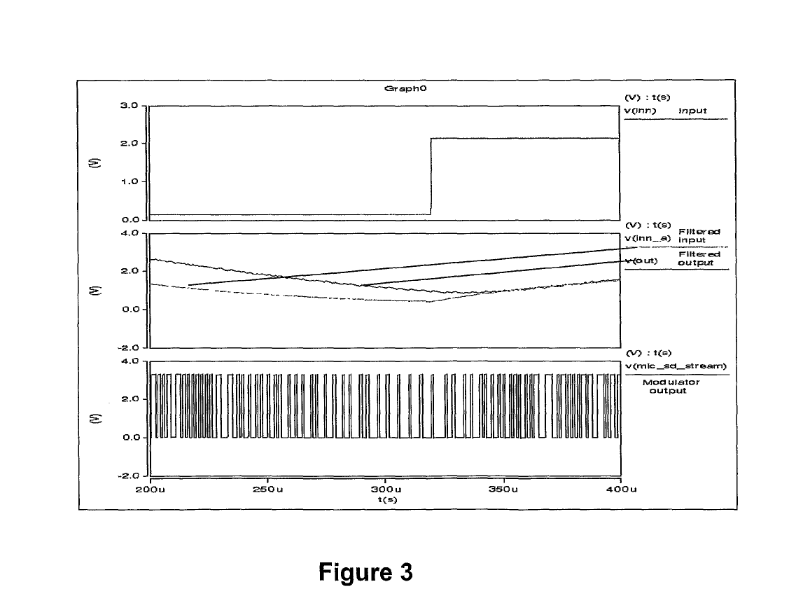

FIG. 1(b) shows a test circuit for testing the analogue part of a sigma-delta ADC 25. This has a differential input 26 that has a filter 28 connected across it. The output 30 of the analogue part of the ADC (marked X in FIG. 1(a)) is connected across a second filter 32. A simple 2-state binary input test vector is passed into the device, as shown in FIGS. 2(a) and 3(a). The input filter moderates the shape of the input digital signal prior to application to the input of the ADC. The modified signal is processed by the analogue circuitry of the ADC. For a second order delta sigma ADC, this circuitry might include two integrators in series, which subtract the input voltage from high or low reference voltage integrating the output and using a one-bit digital to analogue converter as feedback. Delta sigma converters are well documented and the precise detail of operation is not critical for the present invention.

The input test vector propagates through the ADC integrator-stage 14 and over time a series of output pulse is generated, which are short duration compared to the basic frequency of the input signal, as shown in FIGS. 2(c) and 3(c). Averaged over time these pulses constitute a representation of the analogue input voltage. They would normally be kept as a wholly digital signal from this point and require significant digital signal processing capability to extract the data in useable form from this pulse density representation. For example each 8-bit sample in the final digital output might involve digital averaging over 256 clocks (related to pulses) in this stream using a sophisticated high order digital filter.

The output pulse stream from the integrator-stage 14 is directly converted to an analogue signal, optionally without any intervening digital processing. This may be done using a simple RC low pass filter implemented on chip or on the tester load board, although other options are possible. The output of the filter is a crudely filtered version of the pulse stream that represents the original analogue input signal having been processed by the ADC input stage. Plots of the filtered input and filtered output are shown in FIGS. 2(b) and 3(b). The top plot is the digital input signal; the middle upper is the output signal after output RC filter; the middle lower is the input signal after input RC filter and the lower plot is the pulse density modulated output stream.

In practice, the input and output filters are selected so that the input low pass cut-off frequency is lower than the output cut-off frequency. This means the shape is affected less by the output filter and more by the ADC's characteristics. Also the basic clock rate in the pulse stream must be high relative to the output filter's low pass cut-off. The noise ramp signal or the reconstructed signal is related to this and the greater the separation the lower the noise and the greater the accuracy of the resulting test.

Various measurements can be made on the filtered analogue signal to determine if the analogue section of the ADC is working. Differences between this analogue signal and an expected signal, for example a scaled version of the input analogue signal can be used to determine if the analogue section of the ADC is functioning correctly. As a specific example, the output could be checked to verify that changes in the circuit's voltage level at predetermined times occur as expected. A step change in the input test signal will result in step change of the output signal incorporating the response of the input filter the device itself and the output filter. Faults that affect the response timing or amplitude level of the transition will be detectable with a simple check on the timing of the output signal passing through a known threshold. The check can be as gross as a screening test, with the intention of a full test later after scribing, cutting and packaging individual devices.

Optionally, the input and output filter may be selected so that the cut-off frequency of the input filter is lower than that of the output filter. The relationship between the output filter cut off frequency and the clock rate of the ADC sampling clock will determine how much ‘clock’ noise will appear in the filtered output. More specifically, the cut-off frequency of the output filter may be chosen to be lower that the sampling clock rate. This can be chosen to be within manageable limits for the current invention to operate effectively. The digital signal processing in the ADC itself has a much higher order filter to ensure this noise is minimised. However, provided the cut off frequency of the output filter is selected to be low compared to the clock rate, the resulting analogue signal can be sufficiently clock-noise free to allow test measurements to be carried out on it. Higher order passive or active filters can reduce the noise in our set up if necessary.

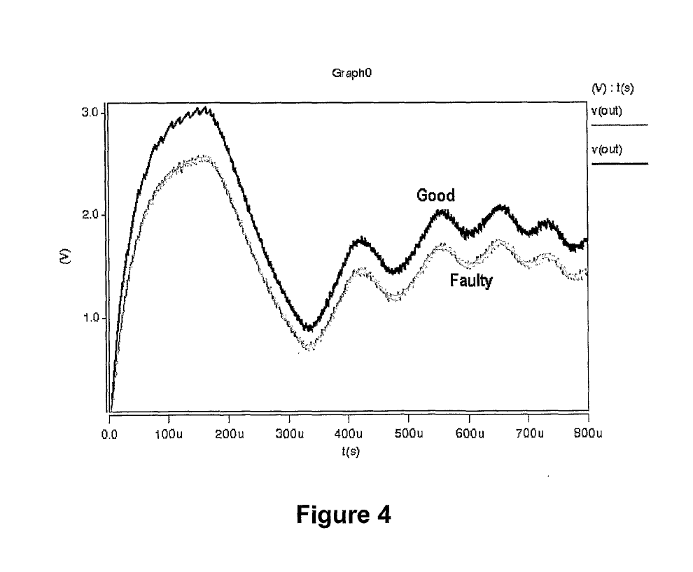

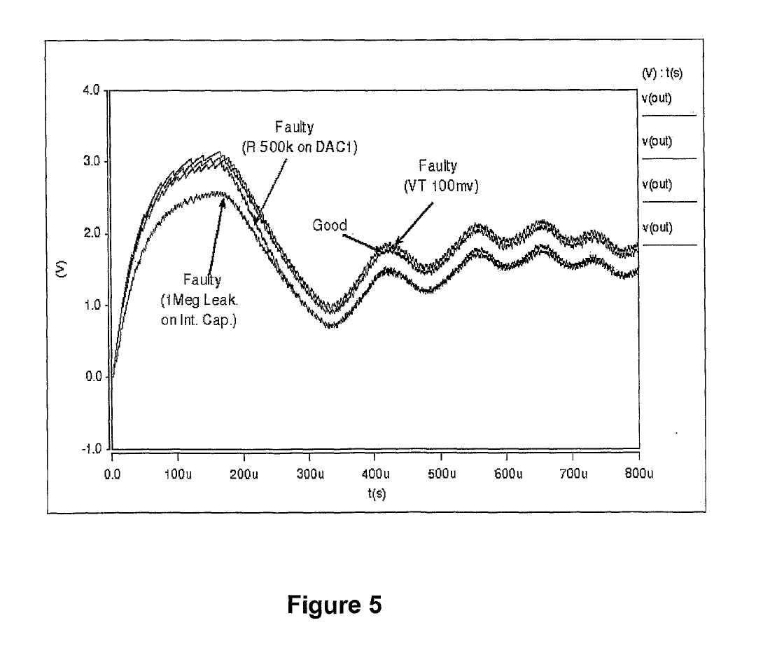

The test in which the invention is embodied has been simulated to successfully identify a number of faulty circuits. FIG. 4 shows simulated output responses from a good circuit and a faulty circuit that has a leaky integrating capacitor. FIG. 5 shows simulated output responses for a good circuit response against various faulty circuit responses. In particular, FIG. 5 shows the outputs for a good circuit; a circuit that has an offset fault of 100 mV, in this case caused by a transistor threshold error; a circuit that has a 1 MOhm leakage resistance on one of its integrating capacitors, and a circuit that has an abnormally high on resistance of 500,000 Ohms on its internal DAC switching transistor. In all cases, these faults can be readily detected.

Conventional approaches to testing delta sigma ADCs involve applying a variety of analogue signals such as sine waves and ramps to the input of the device under test but the settling times particularly for high resolution devices can be extremely long. Since the digital section is a deterministic sequential logic device, albeit an extremely complex one, the precise state of the output can be predicted in response to precise initial logic starting conditions and a predetermined sequence of input states operating from that point.

The bulk of a typical digital delta sigma ADC digital section comprises mainly a high order digital filter. Conventionally, this is tested by applying an analogue input to the analogue input section of the device under test and allowing the pulse density modulated output sequence to settle into a well characterised stream. Unfortunately, the nature of delta sigma ADCs is such that, although the time averaged (effectively the filtered) characteristics of the pulse stream are well characterised, the precise sequence of ones and zeroes in the bit stream cannot be predicted. Indeed, there is typically circuitry in the ADC to ensure this is the case such as pseudo random sequence noise generator to eliminate tones. The converse, however, is not true in as much as the precise digitally processed output from a known input stream will reliably produce a fixed output sampled value at pre-determined times from the beginning.

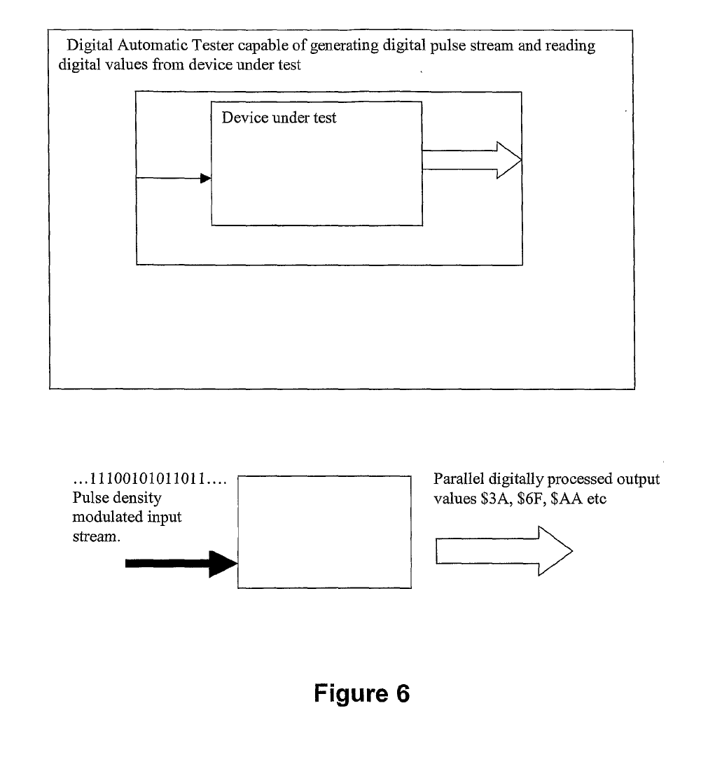

In accordance with a second aspect of the invention, the digital state of the digital section of a delta sigma ADC is forced to a known starting state and thereafter a known sequence comprising a binary pulse density modulated stream is supplied directly to the digital part (overruling any input from the analogue part), as shown in FIG. 6. This forces the digitally processed output to predetermined known output values. Typically, this might be an 8, 14 or even 24 bit values representing the analogue input at different sample times and created by the digital filtering of a long stream of ones and zeros in the digital input signal. The input stream can be designed to force the filter to execute a wide variety of states making use of its various multipliers and adders and other digital circuitry. Thus, the correct operation of the digital circuitry can be verified simply by ensuring the correct digital outputs are received in response to the specified digital input stream with known forced initial states on the logic devices.

In order to improve the effectiveness of circuit testing, the input vector may be selected so that it exaggerates the difference in the output response in terms of timing or voltage levels between known circuits and faulty circuits. For example, the technique described in U.S. Pat. No. 7,174,419, the contents of which are incorporated herein by reference, can be employed. This optimises a binary input test vector based on increasing the output responses differences between nominal circuits and circuits with specified faults in their circuitry.

Faulty devices can be detected comparing the measured output and an expected output. This can be done, using for example a simple digital test resource on automated test equipment, by thresholding the output responses and checking the state of the output signal against a check mask with time slots where the signal must be high, or must be low, or may be indeterminate, in order to pass. This can be done using a simple comparator, the comparator being any one of a voltage comparator; a current comparator and a charge comparator. Being high or low at the wrong time slot can only be caused by a fault so the faulty device is immediately detected.

As noted above, the test circuit(s) of the invention will typically be provided on a circuit board, sometimes referred to as a “load board”, which interfaces between the device under test and the test equipment, although it could be provided integrally with the circuit under test itself. In either case, the invention provides a simple test capable of operating rapidly using simple test equipment giving rapid go/no-go or more detailed information on the state of a device under test.

A skilled person will appreciate that variations of the disclosed arrangements are possible without departing from the invention. For example, whilst the input signal is described as being a simple binary vector, more complex multi-step input signals could be used, or even an analogue input signal. Likewise as well as testing devices that have a single one bit, i.e. binary, output stream, the invention could be applied to devices in which the output is 2, 3 or more, representing say a stream of 3 bits, i.e. able to represent numerically 8 levels instead of the single level described earlier. In this case, it is not possible to simply pass the output signal through an RC filter, and so the density modulated stream is converted using a simple weighted analogue summing filter or with a 3-8 bit decoder, a similar un-weighted summing filter on the load board, or in another variant with some or all additional circuitry on-chip to produce an approximate analogue representation on the sampled input signal.

As a further variation, rather than using a simple RC filter at the output, a higher order active analog filter may employed to produce a better, filtered output signal from the pulses stream. Alternatively, an integrator could be used. Also, the pulse density output signal may be processed prior to being reconverted. For example, between the test circuit and the filter, there may be provided an open drain transistor on or off-chip connected to a higher and potentially more accurate supply voltage which takes the pulse stream (which has accurate transition time information) and produces a higher amplitude binary signal switching between say 0 v and a higher external reference voltage connected through a resistor prior to passing through the simple filter. Accordingly, the above description of the specific embodiment is made by way of example only and not for the purposes of limitation. It will be clear to the skilled person that minor modifications may be made without significant changes to the operation described.

1. A method for testing a circuit that generates an n-bit pulse density modulated output in response to an input signal or combination of input signals, the method comprising: inputting a test signal to the circuit; converting the pulse density modulated output to an analogue signal; and checking the actual analogue output against an expected output.

2. A method as claimed in claim 1 wherein converting the pulse density modulated output to an analogue signal involves filtering the pulse stream.

3. A method as claimed in claim 2 wherein filtering the pulse stream is done using an RC filter and/or an active analogue filter.

4. A method as claimed in claim 1 wherein converting the pulse density modulated output to an analogue signal involves integrating the pulse stream over time.

5. A method as claimed in claim 1 comprising inputting a digital test signal.

6. A method as claimed in claim 5 wherein the digital input test signal is binary or has more than two levels.

7. A method as claimed in claim 5 comprising converting the digital input to an analogue signal prior to inputting it to the circuit under test.

8. A method as claimed in claim 7 wherein converting the digital input to an analogue signal involves filtering the digital input.

9. A method as claimed in claim 8 wherein filtering the digital input involves using an RC filter and/or an active analogue filter.

10. A method as claimed in claim 7 wherein converting the digital input to an analogue signal involves integrating the digital input over time.

11. A method as claimed in claim 1 involving checking the converted signal using a comparator.

12. A method as claimed in claims 11 wherein the comparator is one of a current comparator; a charge comparator or a voltage comparator.

13. A method as claimed in claim 1 comprising using an optimized input test vector.

14. A method as claimed in claim 1 comprising checking the response to the output against an optimized checking mask.

15. A method as claimed in claim 1 wherein the n-bit pulse density modulated output stream comprises a single binary stream.

16. A method as claimed in claim 1 wherein the n-bit pulse density modulated output stream comprises a plurality of binary streams.

17. A system for testing a circuit that has an n-bit pulse density modulated output stream in response to an input signal or combination of input signals, the system comprising: means for inputting a test signal to the circuit; means for converting the pulse density modulated output to an analogue signal; and means for checking the actual analogue output against an expected output.

18. A system as claimed in claim 17 wherein the means for converting the pulse density modulated output to an analogue signal comprise a filter.

19. A system as claimed in claim 18 wherein the filter comprises an RC filter and/or an active analogue filter.

20. A system as claimed in claim 17 wherein the means for converting the pulse density modulated output to an analogue signal comprise an integrator.

21. A system as claimed in claim 17 wherein the input signal is a digital test signal.

22. A system as claimed in claim 21 wherein the digital input test signal is binary or has more than two levels.

23. A system as claimed in claim 21 comprising means for converting the digital input to an analogue signal prior to inputting it to the circuit under test.

24. A system as claimed in claim 23 wherein the means for converting the digital input to an analogue signal comprises a filter.

25. A system as claimed in claim 24 wherein the filter comprises an RC filter and/or an active analogue filter.

26. A system as claimed in claim 17 wherein the means for converting the digital input to an analogue signal comprise an integrator.

27. A system as claimed in claim 17 wherein the means for checking the converted signal comprise a comparator.

28. A system as claimed in claim 27 wherein the comparator is any one of a voltage comparator; a current comparator or a charge comparator.

29. A system as claimed in claim 17 comprising operable to use an optimized input test vector.

30. A system as claimed in any of claims 17 to 29 comprising means for checking the response to the output against an optimized checking mask.

31. A system as claimed in claim 17 wherein the n-bit pulse density modulated output stream comprises a single binary stream.

32. A system as claimed in claim 17 wherein the n-bit pulse density modulated output stream comprises a plurality of binary streams.

33. (canceled)

34. (canceled)

35. (canceled)

36. (canceled)

37. A method as claimed in claim 1, wherein the circuit is an analogue section of an analogue to digital converter that has an n-bit pulse density modulated output stream.

38. A system as claimed in claim 17, wherein the circuit is an analogue section of an analogue to digital converter that has an n-bit pulse density modulated output stream.
